(19) United States
(12) Patent Application Publication
(10) Pub. No.: US 2015/0042386 A1
(43) Pub. Date: Feb. 12, 2015

(54) HIGHLY ACCURATE POWER-ON RESET CIRCUIT WITH LEAST DELAY

(71) Applicant: CIREL SYSTEMS PRIVATE LIMITED, BANGALORE (IN)

(72) Inventors: PRASENJIT BHOWMIK, BANGALORE (IN); PRANJAL PANDEY, BANGALORE (IN)

(73) Assignee: CIREL SYSTEMS PRIVATE LIMITED, BANGALORE (IN)

(21) Appl. No.: 14/140,204

(22) Filed: Dec. 24, 2013

(30) Foreign Application Priority Data
Aug. 6, 2013 (IN) 3523/CHE/2013

(51) Int. Cl. H03K 17/22

(52) U.S. Cl. CPC H03K 17/22
USPC 327/143

(57) ABSTRACT

A power-on reset (POR) circuit for generating a POR signal includes a current source to generate an input current. The input current is a supply voltage dependent current. The POR circuit includes a first diode operable to receive the input current to output a first voltage signal. The first diode is electrically connected in series with a resistor. Further, the POR circuit includes a second diode operable to receive the input current to output a second voltage signal. Further, the POR circuit includes a comparator operable to receive the first voltage signal and the second voltage signal to generate the POR signal at a predefined trip point. The predefined trip point is a point at which the first voltage signal equals the second voltage signal. Furthermore, the POR circuit includes a temperature compensation circuit to compensate for the variation of the predefined trip point.

### TECHNICAL FIELD

The present invention generally relates to power-on reset circuits, and more specifically to a highly accurate power-on reset circuit for generating power-on reset signal with least delay.

### BACKGROUND

Most power supplies cannot deliver required supply voltage level to an integrated circuit instantly. Existing power supplies ramps up the supply voltage level over a period of time, depending on the load of the integrated circuit. For proper functioning of the integrated circuit, it is important to initialize internal digital circuits and memory elements of the integrated circuit at the time of turning ON the power supply. Typically, a power-on reset (POR) circuit that generates a POR signal is employed to keep the internal digital circuits and memory elements initialised to a known value till the power supply reaches valid range of operation.

Various POR circuits exist for generating a POR signal. An example of an existing POR circuit 100 using a differentiator is depicted in FIG. 1. The POR circuit 100 in FIG. 1 includes a differentiator 105, a first invertor 110 and a second invertor 115. An input supply voltage VDD is differentiated and filtered by the RC differentiator 105. The differentiated and filtered signal VC is fed to the first invertor 110. The output from the first inverter 110 is fed to the second inverter 115 to generate a power-on reset signal. The POR circuit 100 generates a POR signal as soon as the signal VC reaches a threshold voltage. The POR circuit 100 is sensitive to threshold voltage, process corners, temperature, and slope of supply voltage, thereby affecting the triggering accuracy of the POR signal. Typically, for the POR circuit 100 to work, the RC time constant needs to be larger than the supply ramp-up slope. As the supply ramp-up slope becomes larger, larger RC time constants are needed. Integrating larger RC values becomes a very difficult task. Hence the POR circuit 100 is typically used for a fast ramp up of supply voltage VDD.

Another example of an existing POR circuit 200 using a voltage reference is depicted in FIG. 2. The POR circuit 200 in FIG. 2 includes a voltage divider 205, an NMOS transistor 210 and an inverter 215. An input supply voltage VDD is divided by the voltage divider 205 to generate a voltage reference signal. The voltage reference signal is fed as a gate voltage to the NMOS transistor 210. As the input supply voltage increases, the gate voltage also increases. When the gate voltage reaches a threshold value, the NMOS transistor 210 generates an output voltage. The output voltage is fed to the inverter 215 to generate a POR signal. In this architecture, the POR signal is subjected to process, voltage and temperature (PVT) variations, since the threshold voltage of the NMOS transistor 210 varies with process and temperature, thereby making the POR circuit 200 inefficient.

FIG. 3 illustrates another way of implementing a POR circuit 300 using a reference voltage. A POR circuit 300 in FIG. 3 includes a circuit 305, a voltage dividing circuit 310 and a comparator 315. An input supply voltage VDD is fed to the circuit 305 to generate a band gap reference voltage VREF. When the input supply voltage VDD reaches to a certain voltage level, the voltage VR generated by the voltage divider circuit 310, increases to a level higher than the band gap reference voltage VREF. At this moment, the comparator 315 will output the POR signal as a HIGH level voltage. However, since the supply voltage VDD is also utilized to bias the circuit 305, when the supply voltage VDD ramps up rapidly, the band gap reference voltage VREF generated by the circuit 305 remains unstable. The reference voltage VREF, generated by the circuit 305, is very sensitive to process, voltage and temperature (PVT) variations. An erroneous reset signal may occur at the output of the comparator 315, which leads the power-on-reset signal to be changed to HIGH level prematurely.

In digital circuits such as state machines, the output of a flip flop is not defined in the initial stage. In such cases, if the POR signal is triggered prematurely before the supply voltage reaches a threshold, the flip flop starts with a faulty logic level which may create functionality issues.

In light of the foregoing discussion there is a need for a circuit to generate a highly accurate power-on reset signal with least delay.

### SUMMARY

The above mentioned need of generating an accurate power-on reset (POR) signal is met by employing a highly accurate POR circuit where the trip point is fairly constant across process voltage and temperature (PVT).

An example of a power-on reset (POR) circuit for generating a POR signal includes a current source to generate an input current. The input current is a supply voltage dependent current. The POR circuit includes a first diode operable to receive the input current to output a first voltage signal. The first diode is electrically connected in series with a resistor. Further, the POR circuit includes a second diode operable to receive the input current to output a second voltage signal. Further, the POR circuit includes a comparator operable to receive the first voltage signal and the second voltage signal to generate the POR signal at a predefined trip point. The predefined trip point is a point at which the first voltage signal equals the second voltage signal. Furthermore, the POR circuit includes a temperature compensation circuit to compensate for the variation of the predefined trip point, wherein the predefined trip point is temperature dependent.

Another example of a power-on-reset (POR) circuit includes a first resistor comprising a first terminal and a second terminal. The first terminal of the first resistor is coupled to a supply voltage and the second terminal of the first resistor is coupled to a first node. The POR circuit includes a second resistor comprising a first terminal and a second terminal. The first terminal of the second resistor is coupled to the supply voltage and the second terminal of the second resistor is coupled to a second node. The POR circuit includes a third resistor comprising a first terminal and a second terminal. The first terminal of the third resistor is coupled to the first node, and the second terminal of the third resistor is coupled to a third node. Further, the POR circuit includes a first diode comprising a positive terminal and a negative terminal. The positive terminal of the first diode is coupled to the third node, and the negative terminal of the first diode is grounded. The POR circuit includes a second diode comprising a positive terminal and a negative terminal. The positive terminal of the second diode is coupled to the second node, and the negative terminal of the second diode is grounded. Furthermore, the POR circuit includes a comparator comprising a non-inverting input terminal, an inverting input terminal, an output terminal, a power supply terminal, and a ground terminal. The non-inverting input terminal is coupled to the first node, the inverting input terminal is coupled to the second node, the power supply terminal is coupled to the supply voltage and the ground terminal is grounded.

The features and advantages described in this summary and in the following detailed description are not all-inclusive, and particularly, many additional features and advantages will be apparent to one of ordinary skill in the relevant art in view of the drawings, specification, and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE FIGURES

In the following drawings like reference numbers are used to refer to like elements. Although the following figures depict various examples of the invention, the invention is not limited to the examples depicted in the figures.

FIG. 1 illustrates a power-on reset (POR) circuit using a differentiator, in accordance with a prior art;

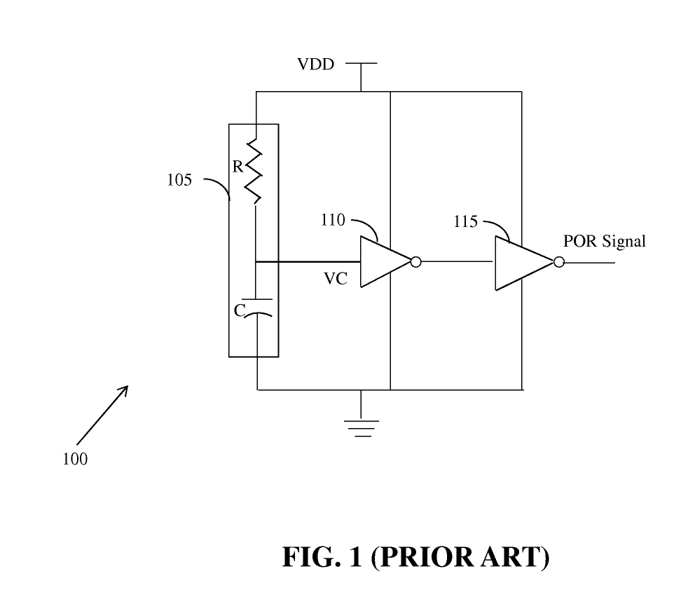

FIG. 2 illustrates a voltage reference based POR circuit, in accordance with another prior art;

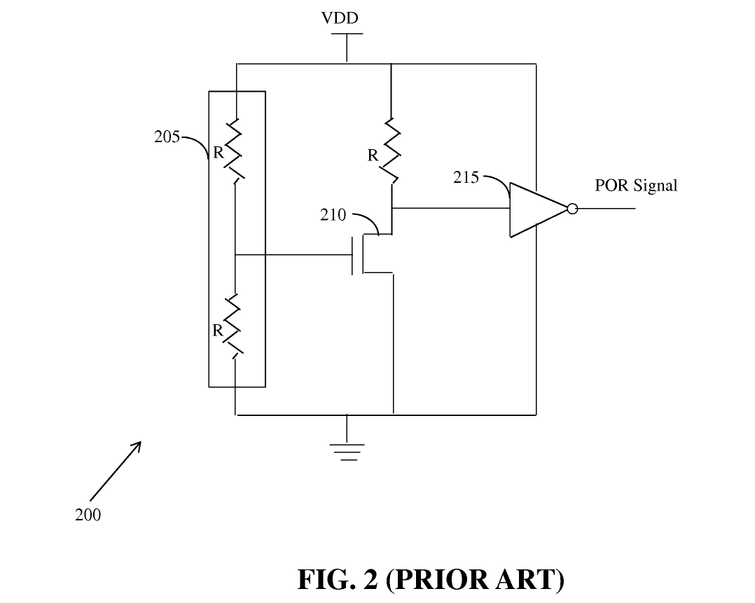

FIG. 3 illustrates another voltage reference based POR circuit, in accordance with yet another prior art;

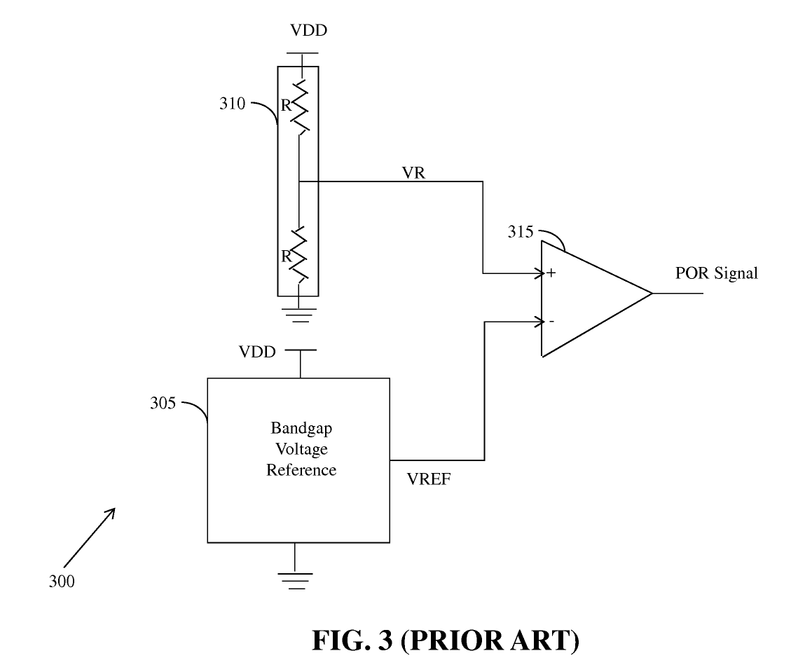

FIG. 4 illustrates a POR circuit with least delay, in accordance with one embodiment of the present invention;

FIG. 5A illustrates a temperature compensated POR circuit with least delay, in accordance with one embodiment of the present invention;

FIG. 5B illustrates the temperature compensated POR circuit with least delay, in accordance with another embodiment of the present invention;

FIG. 6 illustrates a POR circuit implemented by a diode-connected BJT in accordance with one embodiment of the present invention;

FIG. 7 illustrates a POR circuit implemented by a diode-connected MOSFET in accordance with another embodiment of the present invention;

FIG. 8 illustrates a POR circuit, in accordance with yet another embodiment of the present invention;

FIG. 9 depicts the I-V characteristics of a diode, in accordance with one embodiment of the present invention; and

FIG. 10 is a graphical representation of the POR signal generated corresponding to the inputs fed to the comparator.

### DETAILED DESCRIPTION OF THE EMBODIMENTS

In digital circuits such as state machines, the output of a flip flop is not defined till the supply voltage to the circuit reaches a certain minimum level dictated by the process technology. In such cases, if the POR signal is triggered prematurely before the supply voltage reaches a threshold, the memory elements may start with a faulty logic level which creates functionality issues. A power-on reset (POR) circuit that generates a highly accurate POR signal stable across process corners and temperature is explained in the following description.

The circuits generating a POR signal can be grouped into two categories, delay based circuits and voltage level based circuits. The POR circuit mentioned in the present invention is a voltage level based circuit that generates an accurate POR signal with least delay when the input supply reaches a predefined threshold voltage level.

In the present disclosure, relational terms such as first and second, and the like, may be used to distinguish one entity from the other, without necessarily implying any actual relationship or order between such entities. The following detailed description is intended to provide example implementations to one of ordinary skill in the art, and is not intended to limit the invention to the explicit disclosure, as one or ordinary skill in the art will understand that variations can be substituted that are within the scope of the invention as described.

A reference (BGR) circuit has been known as a less temperature-dependent, less power-supply-voltage-dependent, reference voltage generation circuit. The name of the circuit has come from generating a reference voltage almost equal to the silicon's value of 1.205V. The BGR circuit is often used to obtain highly-accurate reference voltages. In a conventional BGR circuit employing bipolar junction transistor (BJT), the collector and base of the BJT are shorted. In such a circuit, the base-emitter voltage will be equal to the forward voltage (with a negative temperature coefficient) of a p-n junction diode or the p-n junction (hereinafter, referred to as the diode). Voltage difference between the forward voltages of diodes which differ in current density has a positive temperature coefficient. The base-emitter voltage is added to a voltage which is an integral multiple of the voltage difference. Thus the reference circuit outputs the resulting voltage (of about 1.25V) with a temperature coefficient of nearly zero. A conventional reference circuit includes three sections: a core where an input voltage is developed and conditioned, a generator, and a current generator. This circuit must operate with a supply voltage that is at least a few hundred millivolts (mV) above the desired voltage (≈1.25 Volts).

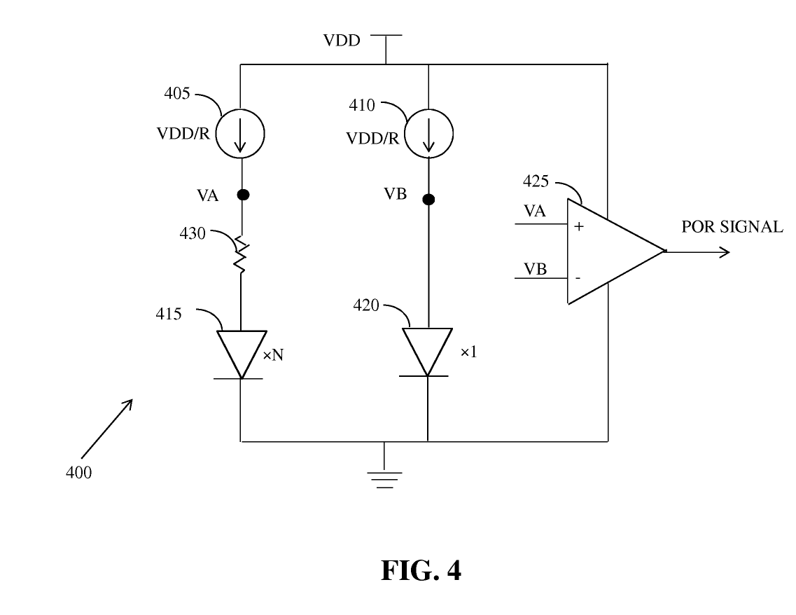

FIG. 4 illustrates a POR circuit 400 generating a POR signal with least delay. The POR circuit 400 includes a first current source 405, a second current source 410, a first diode 415, a second diode 420 and a comparator 425. The first current source 405 generates an input current I1 dependent on supply voltage VDD. The second current source 410 further generates an input current I2 dependent on the supply voltage VDD. Since the first current source 405 and the second current source 410 is coupled to the same supply voltage VDD, the input current I1 and the input current I2 are equal. The input current I1 and the input current I2 is hereinafter referred to as input current I. The first diode 415 is operable to receive the input current I to output a first voltage signal VA. The first diode 415 is electrically connected in series with a resistor 430. The second diode 420 is operable to receive the input current I to output a second voltage signal VB. The first diode 415 in series with the resistor 430 is a first arm of a band-gap circuit. The second diode 420 is a second arm of the band-gap circuit.

In one embodiment of the present invention the first diode 415 and the second diode 420 can be implemented with a p-n junction diode. When implemented with p-n junction diode, the first diode 415 is a first p-n junction diode having a cross sectional area N times compared to the cross sectional area of a second p-n junction diode implemented as the second diode 420 where N is a natural number. In one embodiment, the first diode 415 can be a cluster of p-n junction diodes each having cross sectional area equal to the second p-n junction diode implemented as the second diode 420. The present invention makes use of a cluster of minimum 8 diodes so that the cross sectional area is 8 times that of the single p-n junction diode.

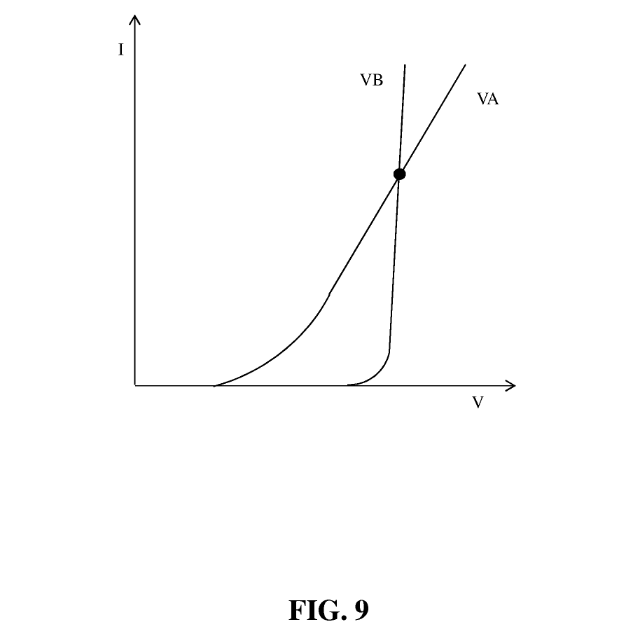

I-V characteristics of the first diode 415 and second diode 420 in conjunction with the resistor 430 is explained in FIG. 9. As the input supply voltage increases the input current I increases, since the input current I is a supply voltage dependent current. The same input current I flows through the first diode 415 and the second diode 420 in conjunction with resistor 430. The first diode 415 has a cross sectional area N times compared to the cross sectional area of the second diode 420. The first voltage signal VA generated across the first diode 415 and the resistor 430 varies linearly with the increase in the input current I, especially for larger values of the input current I. Further as the input current I increases, the second voltage signal VB generated across the second diode 420 increases. The second voltage signal VB reaches the cut-in voltage for a smaller value of the input current I. After reaching the cut-in voltage the second voltage signal VB remains a constant with increase in input current I.

The first voltage signal VA and the second voltage VB is fed as inputs to the comparator 425. The first voltage signal VA is fed to a non-inverting terminal of the comparator 425 and the second voltage signal VB is fed to an inverting terminal of the comparator 425. The comparator 425 produces a LOW level signal when the voltage at the inverting terminal is greater than the voltage at the non-inverting terminal. Further the comparator 425 produces a HIGH level output as soon as the voltage at the non-inverting terminal goes above the voltage at the inverting terminal. The comparator 425 generates a POR signal at a predefined trip point. The predefined trip point is the point at which the first voltage signal VA is equal to the second voltage signal VB.

As the supply voltage increases, the input current I increases. When input current I increases, the first voltage signal VA increases linearly. The second voltage signal VB increases rapidly till it reaches the cut-in voltage and further increases relatively in smaller steps of voltage level. FIG. 9 depicts the variation of the first voltage signal VA and the second voltage signal VB, with respect to the input current I. For small supply voltage VDD the input current I will be small. At small value of the input current I the second voltage signal VB is larger than the first voltage signal VA. As input current I increases, the first voltage signal VA increases linearly and second voltage signal VB almost remains a constant. The first voltage signal VA increases and becomes equal to the second voltage signal VB at a particular point. This point is referred to as trip point. After trip point, the first voltage signal VA increases further and is greater than the second voltage signal VB.

At small value of the supply voltage VDD, the first voltage signal VA fed to the non-inverting terminal is less than the second voltage signal VB fed to the inverting terminal of the comparator 425. Therefore the comparator 425 generates a LOW level signal. After the trip point, for a slight increase in the value of the input current I, the first voltage signal VA goes above the second voltage signal VB. At this moment the comparator 425 generates a POR signal as the output. Thus the POR signal is generated by the POR circuit 400 with minimum delay.

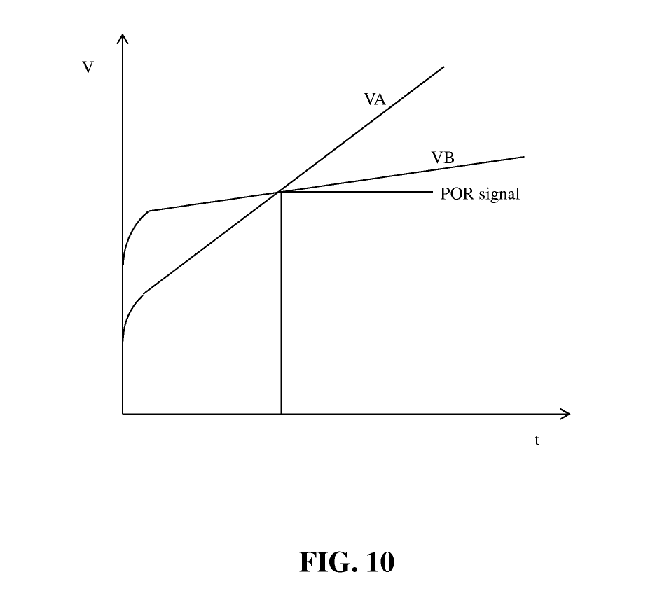

The triggering of the POR signal based on the first voltage signal VA and the second voltage signal VB is depicted in FIG. 10. X axis of the graph in FIG. 10 represents time and Y axis represents voltage. As time increases, the supply voltage VDD ramps up and the input current I increases. As the input current I increases, the first voltage signal VA and the second voltage signal VB increases and becomes equal at trip point. At the trip point the POR signal is triggered.

The expression for the trip point is derived as follows:

The current I1 across the first diode 415 and resistor 430 is

I1=V_{T} log(N)÷Rₚ (Equation 1)

where V_{T}=KT÷q, N is an integral multiple and R_{P} is the resistance value of resistor 430.
The current across the second diode 420 is

I2=V_{Trip}÷R (Equation 2)

where V_{Trip} is the value of supply voltage VDD at trip point and R is the resistance to the flow of current.
Equating the two currents

I1=I2 (Equation 3)

V_{T} log(N)÷Rₚ=V_{Trip}÷R (Equation 4)

V_{Trip}=(R÷Rₚ)×V_{T} log(N) (Equation 5)

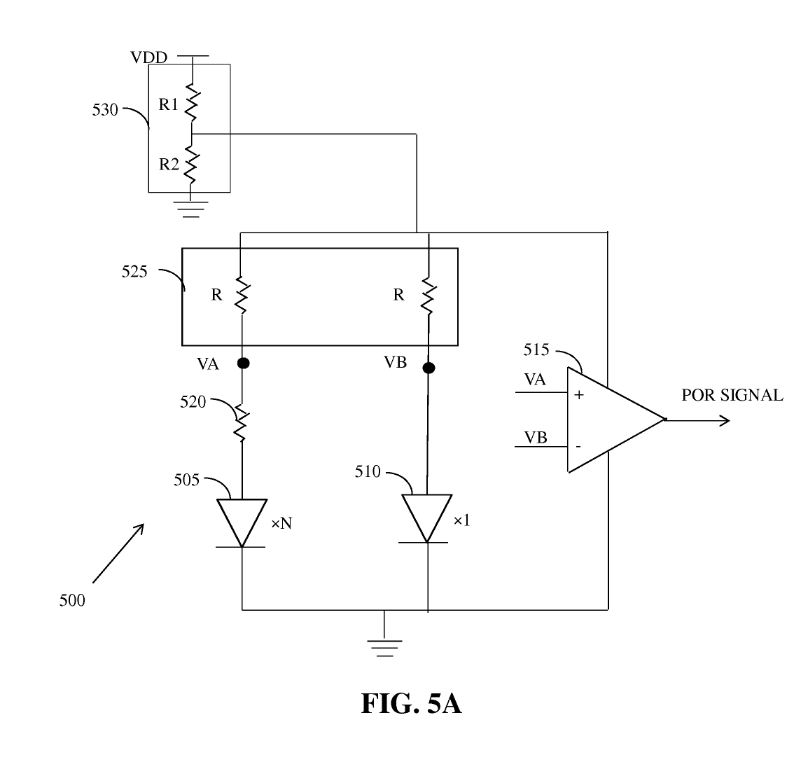

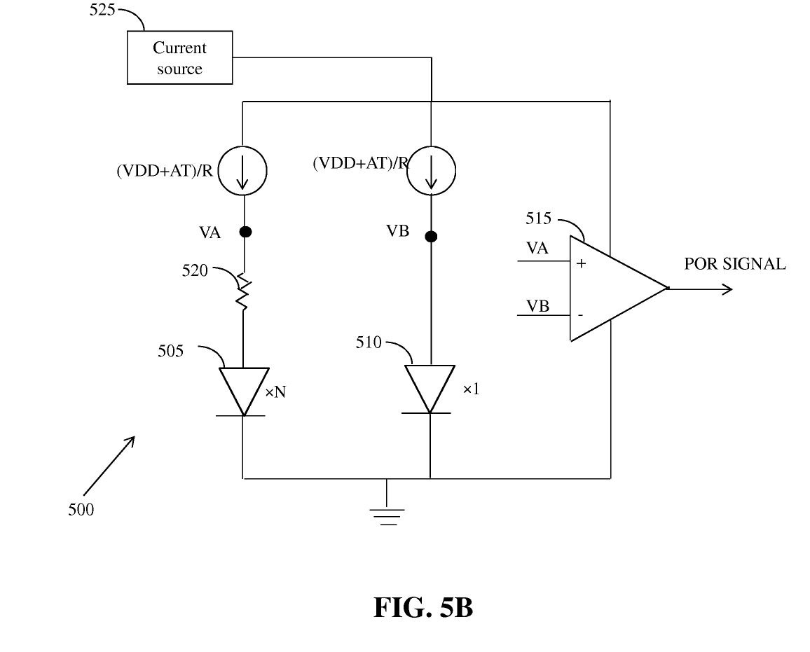

The trip point V_{Trip} is temperature dependent as indicated in Equation 5. The variation of the trip point with temperature can be compensated by different methods. A temperature compensated POR circuit is explained in conjunction with FIG. 5A.

FIG. 5A depicts a temperature compensated POR circuit 500 generating a POR signal with least delay. The POR circuit 500 includes a first diode 505, a second diode 510, a comparator 515 and a temperature compensation circuit 525. The first diode 505 is operable to receive an input current I1 dependent on the supply voltage VDD, to output a first voltage signal VA. The first diode 505 is electrically connected in series with resistor 520. The second diode 510 is operable to receive the input current I2 dependent on the supply voltage VDD, to output a second voltage signal VB.

In one embodiment of the present invention the first diode 505 and the second diode 510 can be implemented with a p-n junction diode. When implemented with p-n junction diode, the first diode 505 is a first p-n junction diode having a cross sectional area N times compared to the cross sectional area of a second p-n junction diode implemented as the second diode 510 where N is a natural number. In one embodiment, the first diode 505 can be a cluster of p-n junction diodes having cross sectional area equal to the second p-n junction diode implemented as the second diode 510. The present invention makes use of a cluster of minimum 8 p-n junction diodes so that cross sectional area is 8 times that of the single p-n junction diode. The first voltage signal VA across the first diode 505 increases linearly with the increase in the input current I1. With the increase in current I2, the voltage VB reaches the cut-in voltage and further remains almost a constant. The variation of first voltage signal VA and the second voltage signal VB with the current I is depicted in FIG. 9.

The first voltage signal VA and the second voltage signal VB is fed as inputs to the comparator 515. The comparator 515 compares the first voltage signal VA and the second voltage signal VB to output a POR signal. The comparator 515 outputs the POR signal at a predefined trip point. The predefined trip point can be defined as the point at which the first voltage signal VA is equal to the second voltage signal VB. From the graph depicted in FIG. 9, it is clear that the first voltage signal VA and the second voltage signal VB become equal at one single point other than the zero point. But the predefined trip point varies with variations in temperature. This is because the first diode 505 and the second diode 510 have a negative temperature coefficient. A temperature compensation circuit 525 is implemented in the POR circuit 500 to compensate the temperature variation.

The temperature compensation circuit 525 includes a first resistor electrically connected in series with the first diode 505 and a second resistor electrically connected in series with the second diode 510. The first resistor and the second resistor is connected in the circuit 500 so that the current generated across the first resistor and the second resistor cancels the effect of negative temperature of first diode 505 and the second diode 510. The expression of the trip point for the temperature compensated POR circuit can be derived as follows.

Let the current generated for temperature compensation across the first resistor and second resistor be

I=(VDD−Vx)÷R (Equation 6)

where VDD is the supply voltage, Vx is the cut-in voltage of the diode and I is the current across the resistor R of the temperature compensated circuit. Current I is fed to the first diode 505 and the second diode 510.
Since the first diode 505 and the second diode 510 is connected to the same supply voltage VDD, current I is equal to the input current I1 and the input current I2.
The input current I1 flowing through the first diode 505 is given by

I1=V_{T} log(N)÷Rₚ (Equation 7)

where V_{T}=KT; q, N is an integral multiple and Rₚ is the resistance value of resistor 520.
The input current I2 flowing through the second diode 510 is given by

I2=(V_{Trip}−Vx)÷R (Equation 8)

where V_{Trip} is the value of input supply voltage VDD at trip point, Vx is the cut-in voltage of the diode and R is the resistance to the flow of current.
Equating the two currents,

I1=I2 (Equation 9)

V_{T} log(N)÷Rₚ=(V_{Trip}−Vx)÷R (Equation 10)

V_{Trip}=Vx+(R÷Rₚ)×V_{T} log(N) (Equation 11)

Since the diode has a negative temperature coefficient, the cut-in voltage Vx has a negative temperature coefficient. The operating point V_{Trip} can be made independent of temperature by choosing value of resistor R such that the negative temperature coefficient of Vx gets cancelled. Thus an accurate operating point independent of the temperature is obtained.

In one embodiment of the present invention the trip point can be pre-programmed. The trip point can be programmed for a range of supply voltage VDD. In order to provide a range of supply voltage the supply voltage VDD is fed through a voltage divider circuit 530. The voltage divider circuit 530 includes a resistor R1 and a resistor R2. The voltage supply fed to the POR circuit 500 depends on the ratio of the value of resistance R1 and R2.

FIG. 5B illustrates another example of a temperature compensated POR circuit 500 generating a POR signal. The temperature compensation circuit 525 is implemented using a current source with positive temperature coefficient to generate a current I required to compensate temperature variation of the trip point. The current I generated by the current source is mirrored into the first diode 505 and the second diode 510. The first diode 505 and the second diode 510 have a negative temperature coefficient of resistance.

Let the current I generated by the current source be

I=(VDD+AT)÷R (Equation 12)

The current I is mirrored into the first diode 505 and second diode 510.
The current I1 across the first diode 505 and the resistance 520 is given by

I1=V_{T} log(N)÷Rₚ (Equation 13)

where V_{T}=KT÷q, N is an integral multiple and Rₚ is the resistance value of resistor 520.
The current I2 across the second diode 510 is given by

I2=(V_{Trip}+AT)÷R (Equation 14)

where V_{Trip} is the value of input supply voltage VDD at trip point.
Since the first diode 505 and the second diode 510 is connected to the same supply voltage VDD, current I is equal to input current I1 and input current I2.
Equating the two currents,

I1=I2 (Equation 15)

V_{T} log(N)÷Rₚ=(V_{Trip}+AT)÷R (Equation 16)

V_{Trip}=[(R÷Rₚ)×V_{T} log(N)]−AT (Equation 17)

The negative temperature coefficient of the diode is cancelled by the positive temperature coefficient of the current ‘AT’ generated by the current source. Therefore the trip point of the POR circuit 500 is fairly constant across process, voltage and temperature (PVT).

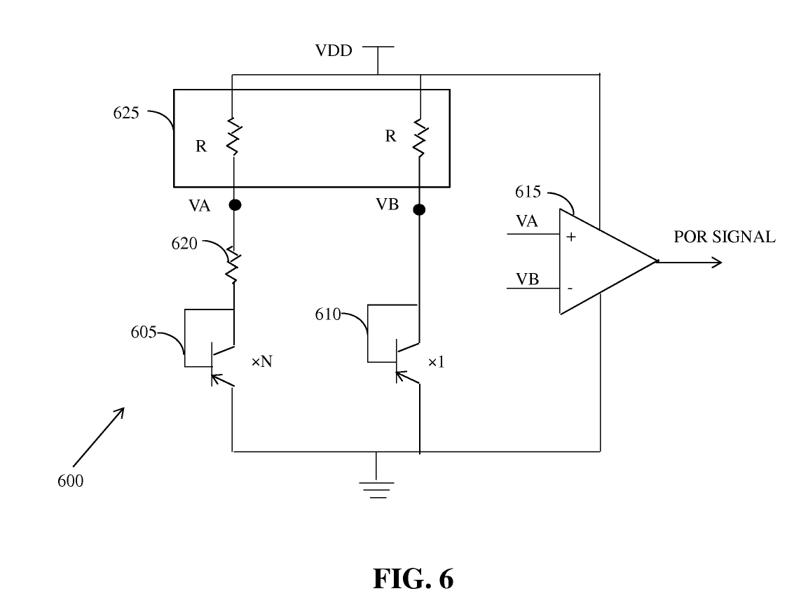

FIG. 6 illustrates another embodiment of the temperature compensated POR circuit 500 in FIG. 5A. In the present embodiment, the first diode 505 and the second diode 510 of the POR circuit 500 are implemented with diode-connected BJTs. The working of the POR circuit 600 in FIG. 6 is as follows. The POR circuit 600 includes a first diode-connected BJT 605, a second diode-connected BJT 610, a comparator 615 and a temperature compensation circuit 625. The first diode-connected BJT 605 receives an input current I1 dependent on the supply voltage to output a first voltage signal VA. The first diode-connected BJT 605 is electrically connected in series to a resistor 620. The second diode-connected BJT 610 receives an input current I2 dependent on the supply voltage, to output a second voltage signal VB.

The first diode-connected BJT 605 is a diode-connected BJT having emitter area N times compared to emitter area of a second diode-connected BJT 610 where N is a natural number. In one embodiment, the first diode-connected BJT 605 can be a cluster of diode-connected BJTs each having emitter area equal to the second diode-connected BJT 610. The present invention makes use of a cluster of minimum 8 diode-connected BJTs so that the emitter area is 8 times that of the second diode-connected BJT 610. The first voltage signal VA, across the first diode-connected BJT 605 and the resistor 620 increases linearly with the increase in the input current I1. The second voltage signal VB reaches the base-emitter voltage, for a smaller value of the input current I2 and further remains almost a constant. The change in first voltage signal VA and the second voltage signal VB with the current is depicted in FIG. 9.

The first voltage signal VA and the second voltage signal VB is fed as inputs to the comparator 615. The comparator 615 compares the first voltage signal VA and the second voltage signal VB to output a POR signal. The comparator 615 outputs a POR signal at a predefined trip point. The predefined trip point can be defined as the point at which the first voltage signal VA is equal to the second voltage signal VB. From the graph depicted in FIG. 9, it is clear that the first voltage signal VA and the second voltage signal VB become equal at one single point other than the zero point. But the predefined trip point varies with variations in temperature. This is because the first diode-connected BJT 605 and the second diode-connected BJT 610 have a negative temperature coefficient. A temperature compensation circuit 625 is implemented in the POR circuit 600 to compensate the variation of the trip point.

The temperature compensation circuit 625 is implemented by connecting a first resistor R in series with the first diode-connected BJT 605. Further, a second resistor R is connected in series with the second diode-connected BJT 610. The first resistor and the second resistor is implemented in the circuit 600, so that the current I generated across the first resistor and the second resistor eliminate the effect of negative temperature coefficient of the first diode-connected BJT 605 and the second diode-connected BJT 610.

Let the current I generated for temperature compensation be

I=(VDD−V_{BE})÷R (Equation 18)

where VDD is the supply voltage, V_{BE} is the base-emitter voltage of the diode-connected BJT and I is the current across the resistor R of the temperature compensated circuit. Current I fed to the first diode-connected BJT 605 and the second diode-connected BJT 610.
Since the first diode-connected BJT 605 and the second diode-connected BJT 610 is connected to the same supply voltage VDD, current I is equal to the input current I1 and the input current I2.
The input current I1 flowing through the first diode-connected BJT 605 is given by

I1=V_{T} log(N)÷Rₚ (Equation 19)

where V_{T}=KT÷q, N is an integral multiple and Rₚ is the resistance value of resistor 620.
The input current I2 flowing through the second diode-connected BJT 610 is given by

I2=(V_{Trip}−V_{BE})÷R (Equation 20)

I2=(V_{Trip}−(V_{BEO}−Y_{T}))÷R (Equation 21)

where V_{Trip} is the value of the input supply voltage VDD at trip point, V_{BE} is the base-emitter voltage of the second diode-connected BJT 610, Y_{T} is the temperature dependent factor of V_{BE} and R is the resistance to the flow of current.
Equating the two currents,

I1=I2 (Equation 22)

V_{T} log(N)÷Rₚ=(V_{Trip}−(V_{BBO}−Y_{T}))÷R (Equation 23)

V_{Trip}=V_{BBO}−Y_{T}+(R÷Rₚ)×V_{T} log(N) (Equation 24)

If the value of R and R_{P} is chosen such that effect of [(R÷Rₚ)×V_{T} log(N)] cancels with Y_{T}, then the trip point will be a constant, independent of temperature. Thus an accurate POR signal is obtained.

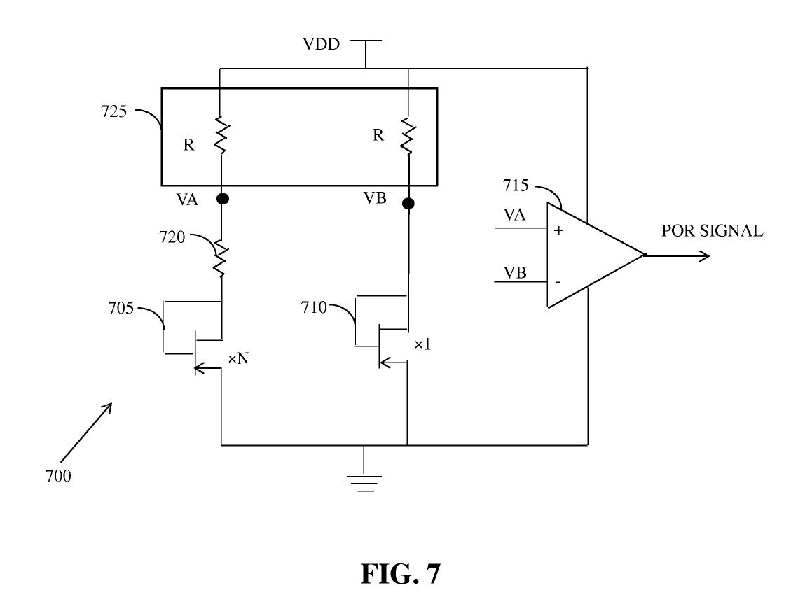

FIG. 7 illustrates yet another embodiment of the temperature compensated POR circuit 500 in FIG. 5A. In the present embodiment the first diode 505 and the second diode 510 of the POR circuit 500 are implemented with diode-connected MOSFETs. The working of the POR circuit 700 in FIG. 7 can be explained as follows. The POR circuit 700 includes a first diode-connected MOSFET 705, a second diode-connected MOSFET 710, a comparator 715 and a temperature compensation circuit 725. The first diode-connected MOSFET 705 receives an input current I1 dependent on the supply voltage to output a first voltage signal VA. The first diode-connected MOSFET 705 is electrically connected in series to a resistor 720. The second diode-connected MOSFET 710 receives an input current I2 dependent on the supply voltage, to output a second voltage signal VB.

The first diode-connected MOSFET 705 is a diode-connected MOSFET having gate area N times compared to gate area of a second diode-connected MOSFET 710, where N is a natural number. In one embodiment the first diode-connected MOSFET 705 can be a cluster of diode-connected MOSFETs each having gate area equal to the second diode-connected MOSFET 710. The present invention makes use of a cluster of minimum 8 diode-connected MOSFETs so that the gate area is 8 times that of the second diode-connected MOSFET 710. The first voltage signal VA increases linearly with the increase in the input current I1. The second voltage signal VB reaches the gate-source voltage, for a smaller value of the input current I2 and further remains almost a constant. The variation of the first voltage signal VA and the second voltage signal VB with the current I is depicted in FIG. 9.

The first voltage signal VA and the second voltage signal VB is fed as inputs to the comparator 715. The comparator 715 compares the first voltage signal VA and the second voltage signal VB to output a POR signal. The comparator 715 outputs a POR signal at a predefined trip point. The predefined trip point can be defined as the point at which the first voltage signal VA is equal to the second voltage signal VB. From the graph depicted in FIG. 9, it is clear that the first voltage signal VA and the second voltage signal VB become equal at one single point other than the zero point. Thus the predefined trip point is a unique point. But the predefined trip point varies with variations in temperature. This is because the first diode-connected MOSFET 705 and the second diode-connected MOSFET 710 have a negative temperature coefficient. A temperature compensation circuit 725 is implemented in the POR circuit 700 to compensate the temperature variation.

The temperature compensation circuit 725 is implemented by connecting a first resistor R in series with the first diode-connected MOSFET 705. Further, a second resistor R is connected in series with the second diode-connected MOSFET 710. The first resistor and the second resistor is implemented in the circuit 700, so that the current generated across the first resistor and the second resistor eliminate the effect of negative temperature coefficient of the first diode-connected MOSFET 705 and the second diode-connected MOSFET 710. Thus a highly accurate POR signal is generated with least delay.

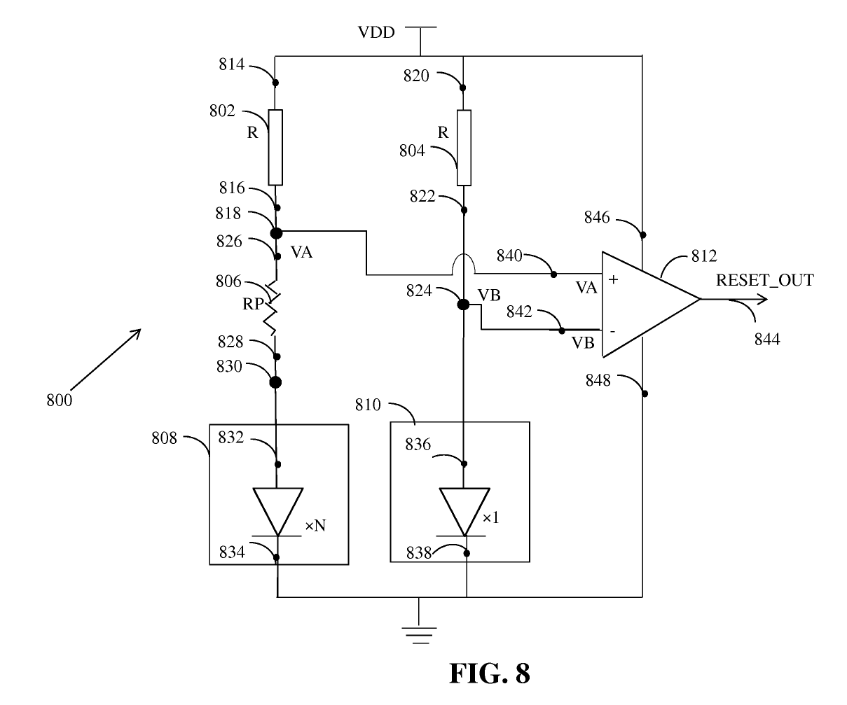

FIG. 8 illustrates yet another embodiment of a temperature compensated POR circuit 800 with least delay. The POR circuit 800 includes a first resistor 802, a second resistor 804, a third resistor 806, a first diode 808, a second diode 810 and a comparator 812. The first resistor 802 includes a first terminal 814 and a second terminal 816. The first terminal 814 is coupled to the supply voltage VDD and the second terminal 816 is coupled to a first node 818 of the POR circuit 800. The second resistor 804 includes a first terminal 820 and a second terminal 822. The first terminal 820 is coupled to the input supply voltage VDD and the second terminal 822 is coupled to a second node 824 of the POR circuit 800. The third resistor 806 includes a first terminal 826 and a second terminal 828. The first terminal 826 is coupled to the first node 818 and the second terminal 828 is coupled to a third node 830 of the POR circuit 800. The first resistor 802 and the second resistor 804 provide temperature compensation for the variations of the trip point of POR circuit 800.

The first diode 808 includes a first terminal 832 and a second terminal 834. The first terminal 832 is coupled to the third node 830 and the second terminal 834 is coupled to ground. The second diode 810 includes a first terminal 836 and a second terminal 838. The first terminal 836 is coupled to the second node 824 and the second terminal 838 is coupled to the ground. In one embodiment of the invention the first diode 808 and the second diode 810 can be implemented by one of a p-n junction diode, a diode-connected BJT and a diode-connected MOSFET. The cross-sectional area of the first diode 808 is an integral multiple of the cross-sectional area of the second diode 810. The minimum value of the integral multiple is 8 in the present invention. The cut-in voltage of the first diode 808 and the second diode 810 changes with the variations in temperature. The first diode 808 and the second diode 810 have a negative temperature coefficient which causes variation of the trip point. The first resistor 802 and the second resistor 804 are connected in the POR circuit 800 to eliminate the effect of temperature variation of the trip point. The value of the first resistor 802 and the second resistor 804 can be pre-programmed. The current across the first resistor 802 and the second resistor 804 has a positive temperature coefficient such that it cancels the negative temperature coefficient of the first diode 808 and the second diode 810 thereby providing temperature compensation.

The comparator 812 includes a non-inverting input terminal 840, an inverting input terminal 842, an output terminal 844, a power supply terminal 846 and a ground terminal 848. The non-inverting input terminal 840 is coupled to the first node 818 to receive a first voltage signal VA generated across the first diode 808 and the resistor 806. The inverting input terminal 842 is coupled to the second node 824 to receive a second voltage signal VB generated across the second diode 810. The power supply terminal 846 is coupled to the input supply voltage VDD and the ground terminal 848 is connected to the ground. The output terminal 844 produces a POR signal based on the first input supply voltage VA and the second input supply voltage VB fed to the comparator 812.

Advantageously the embodiments specified in the present invention triggers a highly accurate power-on reset signal with a minimum delay, thereby protecting the circuits from entering into a faulty state. Unlike the existing prior arts, the present invention triggers a POR signal only at one particular point when the inputs to the comparator are equal. This eliminates premature triggering of the POR signal. Moreover, the circuit can be programmed to work in a range of supply voltage. The trip point can also be pre-programmed. The circuit configuration allows a fairly constant trip point over process, voltage and temperature variation.

In the preceding specification, the present disclosure and its advantages have been described with reference to specific embodiments. However, it will be apparent to a person of ordinary skill in the art that various modifications and changes can be made, without departing from the scope of the present disclosure, as set forth in the claims below. Accordingly, the specification and figures are to be regarded as illustrative examples of the present disclosure, rather than in restrictive sense. All such possible modifications are intended to be included within the scope of present disclosure.

What is claimed is:

1. A power-on reset (POR) circuit for generating a POR signal, the POR circuit comprising:
a current source to generate an input current, wherein the input current is a supply voltage dependent current;
a first diode operable to receive the input current to output a first voltage signal, wherein the first diode is electrically connected in series with a resistor;
a second diode operable to receive the input current to output a second voltage signal;
a comparator operable to receive the first voltage signal and the second voltage signal to generate the POR signal at a predefined trip point, wherein the predefined trip point is a point at which the first voltage signal equals the second voltage signal; and
a temperature compensation circuit to compensate for the variation of the predefined trip point, wherein the predefined trip point is temperature dependent.

2. The POR circuit as claimed in claim 1, wherein the temperature compensation circuit can be implemented by one of:
a first resistor coupled in series with the first diode and a second resistor coupled in series with the second diode; and
a current source with positive temperature coefficient to generate a current required to compensate temperature variation of the predefined trip point, wherein the current generated is mirrored into the first diode and the second diode.

3. The POR circuit as claimed in claim 2, wherein resistance value of the first resistor and the second resistor are pre-programmed.

4. The POR circuit as claimed in claim 1, wherein the first diode and the second diode can be implemented by one of a p-n junction diode, a diode-connected bipolar junction transistor (BJT) and a diode-connected metal oxide semiconductor field effect transistor (MOSFET).

5. The POR circuit as claimed in claim 4, wherein the first diode and the second diode is implemented by the p-n junction diode, wherein the first diode is one of:
a first p-n junction diode having cross sectional area N times compared to the cross sectional area of a second p-n junction diode implemented as the second diode, wherein N is a natural number; and
a cluster of p-n junction diodes with cross sectional area equal to the second p-n junction diode.

6. The POR circuit as claimed in claim 4, wherein the first diode and the second diode is implemented by the diode-connected BJT, wherein the first diode is one of:
a diode-connected BJT having emitter area N times compared to the emitter area of a second diode-connected BJT implemented as the second diode, wherein N is a natural number; and
a cluster of diode-connected BJTs with emitter area equal to the second diode-connected BJT.

7. The POR circuit as claimed in claim 4, wherein the first diode and the second diode is implemented by the diode-connected MOSFET, wherein the first diode is one of:
a diode-connected MOSFET having gate area N times compared to the gate area of a second diode-connected MOSFET implemented as the second diode, wherein N is a natural number; and
a cluster of diode-connected MOSFETs with gate area equal to the second diode-connected MOSFET.

8. The POR circuit as claimed in claim 1, wherein the predefined trip point of the POR circuit is programmable.

9. The POR circuit as claimed in claim 1, wherein the POR circuit generates the POR signal with minimum delay.

10. A power-on-reset (POR) circuit comprising:
a first resistor comprising a first terminal and a second terminal, wherein the first terminal is coupled to a supply voltage and the second terminal is coupled to a first node;
a second resistor comprising a first terminal and a second terminal, wherein the first terminal is coupled to the supply voltage and the second terminal is coupled to a second node;
a third resistor comprising a first terminal and a second terminal, wherein the first terminal is coupled to the first node, and the second terminal is coupled to a third node;
a first diode comprising a positive terminal and a negative terminal, wherein the positive terminal is coupled to the third node, and the negative terminal is grounded;
a second diode comprising a positive terminal and a negative terminal, wherein the positive terminal is coupled to the second node, and the negative terminal is grounded; and
a comparator comprising a non-inverting input terminal, an inverting input terminal, an output terminal, a power supply terminal, and a ground terminal, wherein the non-inverting input terminal is coupled to the first node, the inverting input terminal is coupled to the second node, and the power supply terminal is coupled to the supply voltage.

11. The POR circuit as claimed in claim 10, wherein resistance values of the first resistor and the second resistor are pre-programmed.

12. The POR circuit as claimed in claim 10, wherein the first resistor in conjunction with the second resistor compensates variation of trip point, wherein the trip point is temperature dependent.

13. The POR circuit as claimed in claim 10, wherein the first diode and the second diode can be implemented by one of a p-n junction diode, a diode-connected bipolar junction transistor (BJT) and a diode-connected metal oxide semiconductor field effect transistor (MOSFET).

14. The POR circuit as claimed in claim 13, wherein the first diode and the second diode is implemented by the p-n junction diode, wherein the first diode is one of:
a first p-n junction diode having cross sectional area N times compared to cross sectional area of a second p-n junction diode implemented as the second diode, wherein N is a natural number; and
a cluster of diodes with cross sectional area equal to the second p-n junction diode.

15. The POR circuit as claimed in claim 13, wherein the first diode and the second diode is implemented by the diode-connected BJT, wherein the first diode is one of:
a first diode-connected BJT having emitter area N times compared to the emitter area of a second diode-connected BJT implemented as the second diode, wherein N is a natural number; and
a cluster of diode-connected BJTs with emitter area equal to the second diode-connected BJT.

16. The POR circuit as claimed in claim 13, wherein the first diode and the second diode is implemented by the diode-connected MOSFET, wherein the first diode is one of:
a first diode-connected MOSFET having gate area N times compared to the gate area of a second diode-connected MOSFET implemented as the second diode, wherein N is a natural number; and
a cluster of diode-connected MOSFETs with gate area equal to the second diode-connected MOSFET.
